(19) United States
(12) Patent Application Publication
(10) Pub. No.: US 2024/0057288 A1
(43) Pub. Date: Feb. 15, 2024

(54) SYSTEMS AND METHODS FOR TUNING VALVES OF A LIQUID MANIFOLD

(71) Applicant: Dell Products L.P., Round Rock, TX (US)

(72) Inventors: Richard M. EILAND, Austin, TX (US); Robert B. CURTIS, Georgetown, TX (US)

(73) Assignee: Dell Products L.P., Round Rock, TX (US)

(21) Appl. No.: 17/886,594

(22) Filed: Aug. 12, 2022

(51) Int. Cl. H05K 7/20

(52) U.S. Cl. CPC H05K 7/20281; H05K 7/20272; H05K 7/20627; H05K 7/207

(57) ABSTRACT

A system may include a plurality of information handling systems and a manifold fluidically coupled to each of the plurality of information handling systems via respective fluidic conduits and further configured to couple to a cooling distribution unit, the manifold comprising a plurality of variable valves wherein the variable valves are programmable to control a flow rate of coolant fluid through the variable valves in order to independently control a first flow rate of the coolant fluid to a first information handling system of the plurality of information handling systems and a second flow rate of the coolant fluid to a second information handling system of the plurality of information handling systems.

### TECHNICAL FIELD

The present disclosure relates in general to information handling systems, and more particularly to variable tuning of coolant flow rates in liquid-cooled information handling systems.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction, and damage leading to a shortened component lifespan. Accordingly, air movers (e.g., cooling fans and blowers) have often been used in information handling systems to cool information handling systems and their components.

To control temperature of components of an information handling system, an air mover may direct air over one or more heatsinks thermally coupled to individual components. Traditional approaches to cooling components may include an air cooling system that serves to reject heat of a component to air driven by one or more system-level air movers (e.g., fans) for cooling multiple components of an information handling system in addition to the peripheral component. Another traditional approach may include an indirect cooling system, in which a heat-exchanging cold plate is thermally coupled to the component, and a chilled fluid is passed through conduits internal to the cold plate to remove heat from the component.

In a liquid cooled system for information handling systems, liquid cooling manifolds facilitate distribution of coolant fluid from a cooling distribution unit (CDU) to individual information handling systems and/or cold plate loops. Typically, these manifolds are designed for full rack level installments or individual chassis level implementations for systems such as modular blade chasses. Nodes may be easily connected/disconnected via quick disconnect ports along the manifold. However, as computing nodes are added/removed, the overall impedance of the fluid network may be altered and may impact the flow rate to individual nodes. Even when a rack manifold is fully populated with identical (homogeneous) equipment and liquid cooling nodes, uneven distribution of coolant fluid may occur due to friction losses in the fluidic channels. The complexity of this fluid network may become greater when mixed (heterogenous) equipment and liquid cooling nodes are installed in a rack. Uneven distribution of fluid flow across nodes may occur with potential impact to system thermal performance and/or overall pump efficiency.

### SUMMARY

In accordance with the teachings of the present disclosure, the disadvantages and problems associated with liquid distribution in liquid cooling systems may be substantially reduced or eliminated.

In accordance with embodiments of the present disclosure, a system may include a plurality of information handling systems and a manifold fluidically coupled to each of the plurality of information handling systems via respective fluidic conduits and further configured to couple to a cooling distribution unit, the manifold comprising a plurality of variable valves wherein the variable valves are programmable to control a flow rate of coolant fluid through the variable valves in order to independently control a first flow rate of the coolant fluid to a first information handling system of the plurality of information handling systems and a second flow rate of the coolant fluid to a second information handling system of the plurality of information handling systems.

In accordance with these and other embodiments of the present disclosure, a manifold for use in a fluidic distribution network may include a plurality of fittings, each of the plurality of fittings configured to couple to a respective information handling system of a plurality of information handling systems via a respective fluidic conduit. The fluidic distribution network may also include a plurality of variable valves wherein the variable valves are programmable to control a flow rate of coolant fluid through the variable valves in order to independently control a first flow rate of the coolant fluid to a first information handling system of the plurality of information handling systems and a second flow rate of the coolant fluid to a second information handling system of the plurality of information handling systems.

In accordance with these and other embodiments of the present disclosure, a method may include fluidically coupling a manifold to each of a plurality of information handling systems via respective fluidic conduits and further configured to couple to a cooling distribution unit, the manifold comprising a plurality of variable valves wherein the variable valves are programmable to control a flow rate of coolant fluid through the variable valves in order to independently control a first flow rate of the coolant fluid to a first information handling system of the plurality of information handling systems and a second flow rate of the coolant fluid to a second information handling system of the plurality of information handling systems and fluidically coupling the manifold to a cooling distribution unit.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example server enclosure housing a plurality of information handling systems, in accordance with embodiments of the present disclosure; and

FIG. 2 illustrates a block diagram of selected components of another example server enclosure housing a plurality of information handling systems, in accordance with embodiments of the present disclosure.

### DETAILED DESCRIPTION

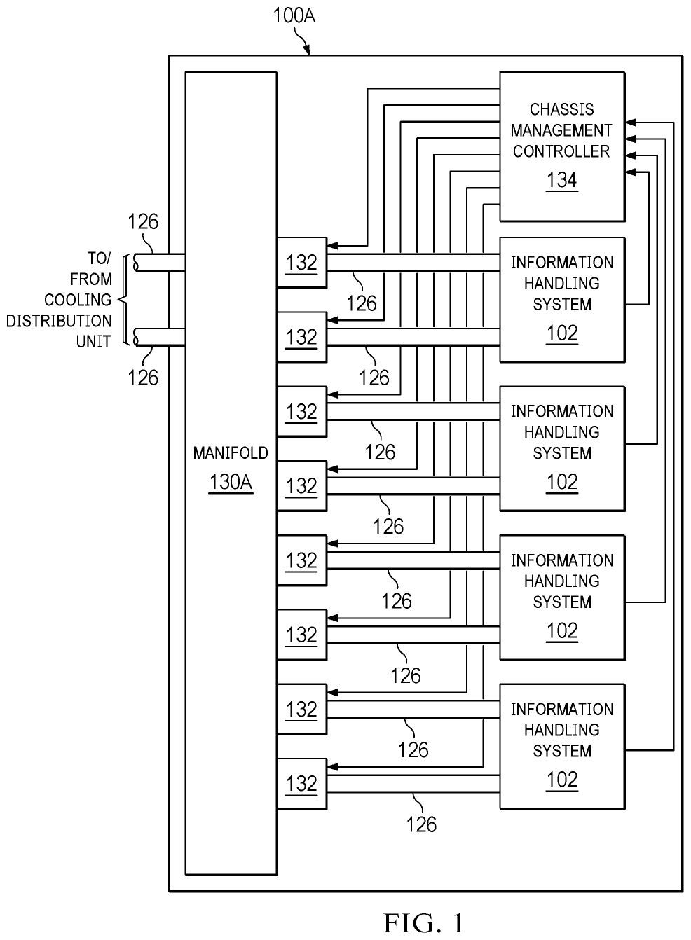

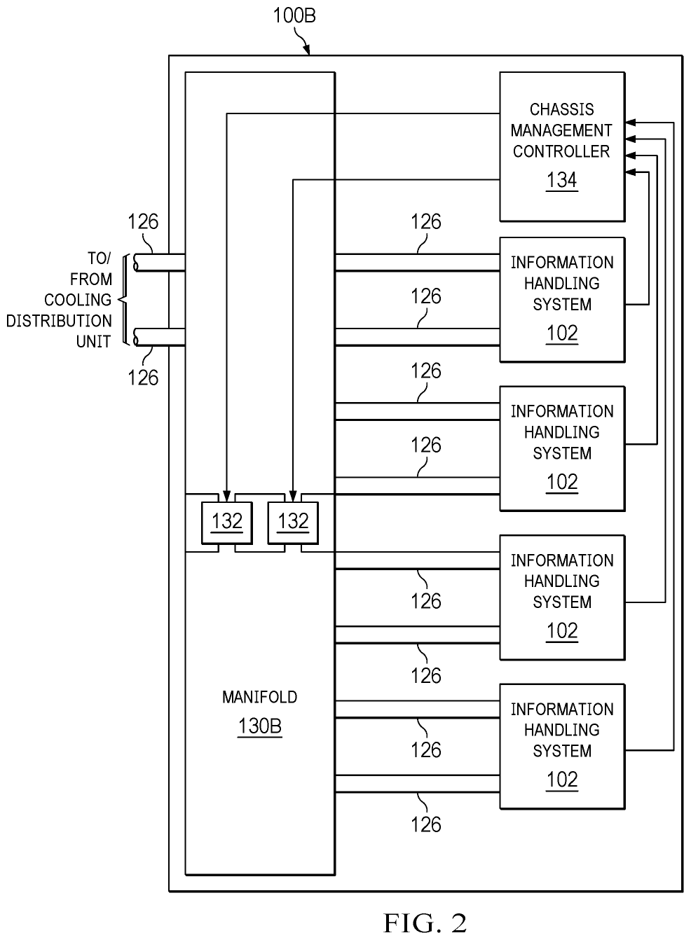

Preferred embodiments and their advantages are best understood by reference to FIGS. 1 and 2, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of selected components of an example server enclosure 100A housing a plurality of information handling systems 102, in accordance with embodiments of the present disclosure. Enclosure 100A may comprise any suitable housing or other container for housing a plurality of information handling systems 102, and may be constructed from any suitable materials, including metal and/or plastic. As shown in FIG. 1, in addition to housing a plurality of information handling systems 102, enclosure 100A may also include a manifold 130A, variable valves 132, a chassis management controller 134, and a plurality of fluidic conduits 126.

Manifold 130A may include any system, device, or apparatus configured to receive coolant fluid from a centralized fluid cooling and distribution system (e.g., a radiator for cooling coolant fluid), distribute (e.g., under pressure applied from a pump of the centralized fluid cooling and distribution system) such coolant fluid to the plurality of information handling systems 102 via fluidic conduits 126 fluidically coupled to manifold 130A, receive such coolant fluid back from information handling systems 102 via fluidic conduits 126 fluidically coupled to manifold 130A, and then distribute coolant fluid back to the centralized fluid cooling and distribution system.

Thus, in operation, manifold 130A may receive cooled coolant fluid from the centralized fluid cooling and distribution system (e.g., a radiator) and convey the coolant fluid to each of information handling systems 102. Each information handling system 102 may have its own internal coolant fluid distribution network, such that coolant fluid distributed to each information handling system 102 may cool components of such information handling system 102 on account of heat transfer from such components to the coolant fluid. After flowing through the internal coolant fluid distribution network of an information handling system 102, the heated coolant fluid may return to manifold 130A. Manifold 130A may be constructed to isolate the cooled coolant fluid received from the centralized fluid cooling and distribution system from the heated coolant fluid received from information handling systems 102. Manifold 130A may further route the heated coolant fluid back to the centralized fluid cooling and distribution system, where the coolant fluid may be cooled and recirculated back to manifold 130A.

As also shown, manifold 130A may include at its outputs to information handling systems 102 (e.g., coupled between fluidic channels within manifold 130A and quick disconnect fluid fittings of manifold 130A for fluidically coupling to fluidic conduits 126) a plurality of variable valves 132. A variable valve 132 may comprise any suitable system, device, or apparatus that regulates, directs, and/or controls the flow of a fluid (e.g., a coolant liquid flowing between fluidic conduits 126 and manifold 130A) by opening, closing, or partially obstructing one or more passageways. When a variable valve 132 is open, coolant liquid may flow in a direction from higher pressure to lower pressure. In addition, a variable valve 132 may be controlled (either manually or automatically) to vary a flow rate of coolant fluid through such valve.

In some embodiments, the operation of a variable valve 132 (e.g., opening and closing, size of an aperture of a variable valve 132) may be controlled by one or more control signals communicated from chassis management controller 134, as shown in FIG. 1. In other embodiments, the operation of a variable valve 132 may be manually controlled by a person.

Although variable valves 132 are shown in FIG. 1 as being coupled to both the fluid inlets of information handling systems 102 and the fluid outlets of information handling systems 102, in some embodiments, variable valves 132 may be present only at fluid inlets of information handling systems 102 or only at fluid outlets of information handling systems 102.

Chassis management controller 134 may comprise any system, device, or apparatus configured to facilitate management and/or control of enclosure 100A and/or one or more of its component information handling systems 102. Chassis management controller 134 may be configured to issue commands and/or other signals to manage and/or control information handling system 102 and/or its information handling resources. Chassis management controller 134 may comprise a microprocessor, microcontroller, DSP, ASIC, field programmable gate array (“FPGA”), EEPROM, or any combination thereof. Chassis management controller 134 also may be configured to provide out-of-band management facilities for management of enclosure 100A, for example via a management console communicatively coupled to chassis management controller 134. Such management may be made by chassis management controller 134 even if enclosure 100A and its information handling systems 102 are powered off or powered to a standby state.

In operation, chassis management controller 134 may receive telemetry information from information handling systems 102 and/or from other sources of telemetry information (e.g., sensors). Such telemetry may include temperature information associated with an information handling system 102 or its components, a flow rate within one or more fluidic channels of enclosure 100A, a pressure within one or more fluidic channels of enclosure 100A, and/or any other suitable information. Although not shown in FIG. 1 for purposes of clarity and exposition, enclosure 100A and/or components thereof may include suitable sensors for measuring or estimating such telemetry information, including without limitation temperature sensors, flow rate sensors, and/or pressure sensors.

In response to such telemetry information, chassis management controller 134 may control flow rates of coolant fluid through each of variable valves 132. For example, in its simplest form, such control may include monitoring temperatures associated with each information handling system 102 and, in response to a temperature within an information handling system 102 rising above a threshold, increasing a flow rate of coolant fluid to such information handling system 102 (and, in some instances, decreasing a flow rate of coolant fluid to other information handling systems 102). However, control with more complex algorithms may be used, including using empirically-based formulae and/or applying machine learning/neural networks to optimize control of coolant fluid flow rate in order to maintain thermal requirements. Accordingly, chassis management controller 134 together with variable valves 132 may enable a closed feedback control loop in order to maintain thermal requirements.

FIG. 2 illustrates a block diagram of selected components of an example server enclosure 100B housing a plurality of information handling systems 102, in accordance with embodiments of the present disclosure. Enclosure 100B may comprise any suitable housing or other container for housing a plurality of information handling systems 102, and may be constructed from any suitable materials, including metal and/or plastic. Enclosure 100B depicted in FIG. 2 may be similar in many respects to enclosure 100A of FIG. 1. Accordingly, only certain differences between enclosure 100B and enclosure 100A may be described below.

For example, instead of variable valves 132 located at the inlet of a manifold as is the case in FIG. 1, enclosure 100B may include a manifold 130B divided into a plurality of portions, wherein each portion is fluidically coupled to one or more information handling systems 102 dedicated to such portion. Each portion may be coupled to another portion via one or more variable valves 132 which may control fluid flow between the portions. In some embodiments, each of variable valves 132 may be controlled by one or more control signals from chassis management controller 134, similar to that of FIG. 1. In other embodiments, each of variable valves 132 may be manually controlled by a person. Further, in enclosure 100B, chassis management controller 134 may control flow rates of coolant fluid through variable valves 132 in response to telemetry data. Thus, in effect, enclosure 100B will include a plurality of zones of information handling systems 102, wherein each information handling system 102 within the same zone is fluidically coupled to the same portion of manifold 130B, and coolant fluid flow rates to and from information handling systems 102 within a zone may be controlled based on telemetry information associated with such zone.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A system comprising:
a plurality of information handling systems; and
a manifold fluidically coupled to each of the plurality of information handling systems via respective fluidic conduits and further configured to couple to a cooling distribution unit, the manifold comprising a plurality of variable valves wherein the variable valves are programmable to control a flow rate of coolant fluid through the variable valves in order to independently control a first flow rate of the coolant fluid to a first information handling system of the plurality of information handling systems and a second flow rate of the coolant fluid to a second information handling system of the plurality of information handling systems.

2. The system of claim 1, wherein each variable valve is manually programmable by a person.

3. The system of claim 1, wherein each variable valve is automatically programmable via one or more control signals communicated from a controller communicatively coupled to the variable valves.

4. The system of claim 1, further comprising a controller communicatively coupled to each of the plurality of variable valves and configured to:
receive telemetry information regarding the plurality of information handling systems; and
based on the telemetry information, generate one or more control signals to the plurality of variable valves in order to individually control a respective flow rate of coolant fluid through each of the plurality of variable valves.

5. The system of claim 4, wherein the telemetry information includes one or more of temperature information, flow rate information associated with the coolant fluid, and pressure information associated with the coolant fluid.

6. The system of claim 1, wherein each of the plurality of variable valves is fluidically coupled between internal fluidic channels of the manifold and a respective fitting for fluidically coupling a fluidic conduit to the manifold.

7. The system of claim 1, wherein each of the plurality of variable valves is fluidically coupled between different portions of the manifold.

8. A manifold for use in a fluidic distribution network, comprising:
a plurality of fittings, each of the plurality of fittings configured to couple to a respective information handling system of a plurality of information handling systems via a respective fluidic conduit; and
a plurality of variable valves wherein the variable valves are programmable to control a flow rate of coolant fluid through the variable valves in order to independently control a first flow rate of the coolant fluid to a first information handling system of the plurality of information handling systems and a second flow rate of the coolant fluid to a second information handling system of the plurality of information handling systems.

9. The manifold of claim 8, wherein each variable valve is manually programmable by a person.

10. The manifold of claim 8, wherein each variable valve is automatically programmable via one or more control signals communicated from a controller communicatively coupled to the variable valves.

11. The manifold of claim 10, wherein the one or more signals are based on telemetry information regarding the plurality of information handling systems.

12. The manifold of claim 11, wherein the telemetry information includes one or more of temperature information, flow rate information associated with the coolant fluid, and pressure information associated with the coolant fluid.

13. The manifold of claim 8, wherein each of the plurality of variable valves is fluidically coupled between internal fluidic channels of the manifold and a respective fitting for fluidically coupling a fluidic conduit to the manifold.

14. The manifold of claim 8, wherein each of the plurality of variable valves is fluidically coupled between different portions of the manifold.

15. A method comprising:
fluidically coupling a manifold to each of a plurality of information handling systems via respective fluidic conduits and further configured to couple to a cooling distribution unit, the manifold comprising a plurality of variable valves wherein the variable valves are programmable to control a flow rate of coolant fluid through the variable valves in order to independently control a first flow rate of the coolant fluid to a first information handling system of the plurality of information handling systems and a second flow rate of the coolant fluid to a second information handling system of the plurality of information handling systems; and
fluidically coupling the manifold to a cooling distribution unit.

16. The method of claim 15, wherein each variable valve is manually programmable by a person.

17. The method of claim 15, further comprising automatically controlling each variable valve via one or more control signals communicated from a controller communicatively coupled to the variable valves.

18. The method of claim 17, wherein the one or more signals are based on telemetry information regarding the plurality of information handling systems.

19. The method of claim 18, wherein the telemetry information includes one or more of temperature information, flow rate information associated with the coolant fluid, and pressure information associated with the coolant fluid.

20. The method of claim 15, wherein each of the plurality of variable valves is fluidically coupled between internal fluidic channels of the manifold and a respective fitting for fluidically coupling a fluidic conduit to the manifold.

21. The method of claim 15, wherein each of the plurality of variable valves is fluidically coupled between different portions of the manifold.
